(19) United States
(12) Patent Application Publication
(10) Pub. No.: US 2008/0087981 A1
(43) Pub. Date: Apr. 17, 2008

(54) SEMICONDUCTOR DEVICE AND METHOD OF FABRICATING THE SAME

(75) Inventor: Koichi Matsuno, Mie-gun (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/866,147

(22) Filed: Oct. 2, 2007

(30) Foreign Application Priority Data
Oct. 2, 2006 (JP) 2006-270660

(51) Int. Cl. H01L 29/00; H01L 21/762

(52) U.S. Cl. 257/510; 438/425; 257/E29.001; 257/E21.553

(57) ABSTRACT

A semiconductor device includes a semiconductor substrate formed with at least two element isolation trenches having a first opening width and a second opening width larger than the first opening width, respectively, a non-coating type silicon oxide film formed along an inner surface of each element isolation trench so as to have a film thickness equal to or larger than 23 nm, and a coating type silicon oxide film formed inside the non-coating type silicon oxide film in each element isolation trench.

### CROSS-REFERENCE TO RELATED APPLICATIONS

This application is based on and claims the benefit of priority from the prior Japanese Patent Application No. 2006-270660, filed on Oct. 2, 2006, the entire contents of which are incorporated herein by reference.

### BACKGROUND OF THE INVENTION

1. Field of the Invention

The present invention relates to a semiconductor device provided with an element isolation region of the shallow trench isolation (STI) structure and a method of fabricating the semiconductor device.

2. Description of the Related Art

A shallow trench isolation (STI) method has recently been employed as a method for isolation between elements formed in semiconductor devices. In the STI method, an element isolation trench is formed in an upper surface of a semiconductor substrate, and an insulating film is buried in the element isolation trench so that a predetermined insulating performance is retained. A method for burying a silicon oxide film by high density plasma (HDP)-chemical vapor deposition (CVD) method is employed for an element isolation region formed by the STI method.

However, recent miniaturization of elements and reduction in the design rules have increased an aspect ratio in the case where a silicon oxide film is buried in the element isolation trench by the above-described method. As a result, it has become difficult to fill the element isolation region sufficiently. To overcome the problem, for example, JP-A-2003-31650 discloses a technique that a silicon oxide film is formed along an inner surface of the element isolation trench by the HDPCVD method and subsequently, an insulating film of a coating type is formed so as to fill a space inside the silicon oxide film by a coating method.

When the technique disclosed in JP-A-2003-31650 is applied, the following technical problem arises in a semiconductor device provided with a plurality of element isolation trenches having different opening widths. A coating material is applied for formation of an insulating film of the coating type after a first silicon oxide film has been formed by the CVD method. Subsequently, the coating material needs to be thermally treated for the purpose of converting the coating material to a second silicon oxide film. The reason for the thermal treatment is that since the coating material has a low density, the etching rate is increased such that the film thickness control becomes difficult during a forming process.

However, since the coating material has a larger film shrinkage factor than the silicon oxide film formed by the CVD method, peeling occurs in the silicon oxide film or crack is produced. In this case, particularly when an electrically conductive film such as polycrystalline silicon for control gate needs to be deposited on the silicon oxide films, the conductive film enters a peeled portion or crack, whereupon a desired characteristic cannot be obtained.

### BRIEF SUMMARY OF THE INVENTION

Therefore, an object of the present invention is to provide a semiconductor device in which crack can be prevented and peeling can be suppressed even when the element isolation region is provided with element isolation trenches with different opening widths, and a method fabricating the semiconductor device.

In one aspect, the present invention provides a semiconductor device comprising a semiconductor substrate formed with at least two element isolation trenches having a first opening width and a second opening width larger than the first opening width, respectively, a non-coating type silicon oxide film formed along an inner surface of each element isolation trench so as to have a film thickness equal to or larger than 23 nm, and a coating type silicon oxide film formed inside the non-coating type silicon oxide film in each element isolation trench.

The invention also provides a semiconductor device comprising a semiconductor substrate including a memory cell region having a plurality of first element isolation trenches with first opening widths respectively and a plurality of memory cell elements formed on first active regions divided by the first element isolation trenches, and a peripheral circuit region having a second element isolation trench with a second opening width larger than the first opening widths of the first element isolation trenches, and having peripheral circuit elements formed on second active regions divided by the second element isolation trenches, a non-coating type silicon oxide film formed along an inner surface of each element isolation trench so as to have a film thickness equal to or larger than 23 nm, and a coating type silicon oxide film formed inside the non-coating type silicon oxide film in each element isolation trench.

In another aspect, the invention provides a method of fabricating a semiconductor device, comprising forming in a semiconductor substrate a plurality of element isolation trenches having different opening widths, forming a non-coating type silicon oxide film along an inner surface of each element isolation trench so that the non-coating type silicon oxide film has a film thickness equal to or larger than 23 nm, and forming a coating type silicon oxide film inside the non-coating type silicon oxide film formed in each element isolation trench.

### BRIEF DESCRIPTION OF THE DRAWINGS

Other objects, features and advantages of the present invention will become clear upon reviewing the following description of one embodiment with reference to the accompanying drawings, in which:

FIG. 1 shows an electrical arrangement of a memory cell region of a semiconductor device in accordance with one embodiment of the present invention;

FIG. 2 is a plan view showing a frame format of part of the memory cell region;

FIG. 3 is a plan view showing a frame format of part of a peripheral circuit region;

FIG. 4A is a sectional view showing a frame format of part of the memory cell region;

FIG. 4B is a sectional view showing a frame format of part of the peripheral circuit region;

FIGS. 5A, 6A, 7A, 8A, 9A, 10A, 11A, 12A, 13A and 14A are sectional views showing a frame format of the memory cell region during fabrication (Nos. 1 to 10);

FIGS. 5B, 6B, 7B, 8B, 9B, 10B, 11B, 12B, 13B and 14B are sectional views showing a frame format of the peripheral circuit region during fabrication (Nos. 1 to 10);

FIG. 15 is a graph showing a sidewall film thickness dependency of defect density in the peripheral circuit region; and

FIG. 16 is a graph showing a sidewall film thickness dependency of measured voltage depending upon an electronic trap amount.

### DETAILED DESCRIPTION OF THE INVENTION

One embodiment of the present invention will be described with reference to the accompanying drawings. The invention is applied to a NAND flash memory in the embodiment. Identical or similar parts are labeled by the same reference symbols throughout the figures. It is noted that the figures illustrate frame formats of the device and the relationship between a thickness and planar dimension, thickness ratio of each layer and the like differ from those of actually fabricated devices.

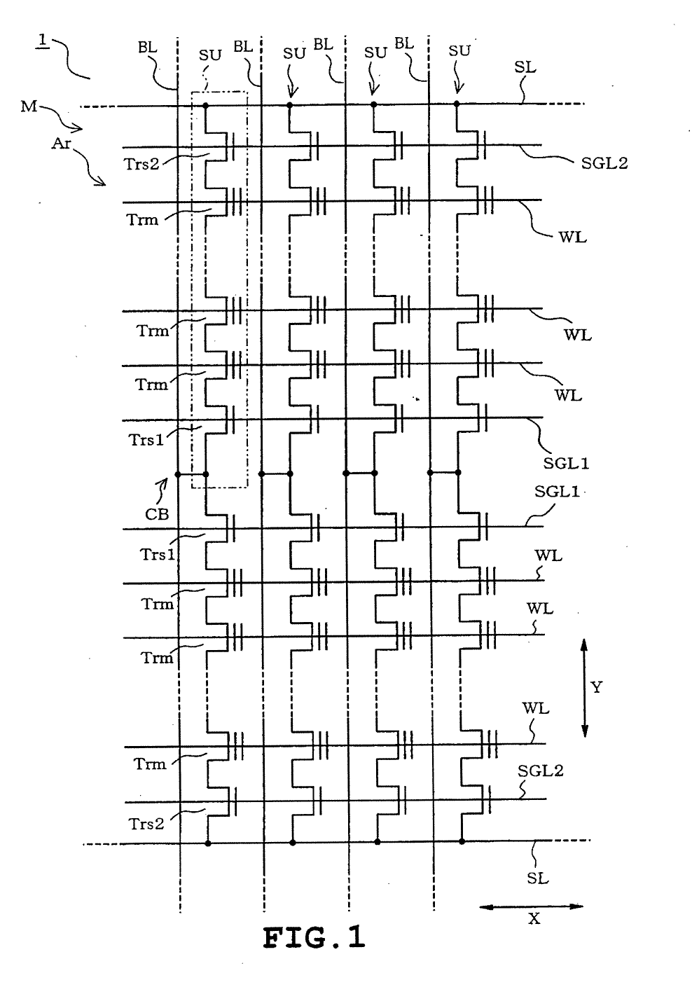

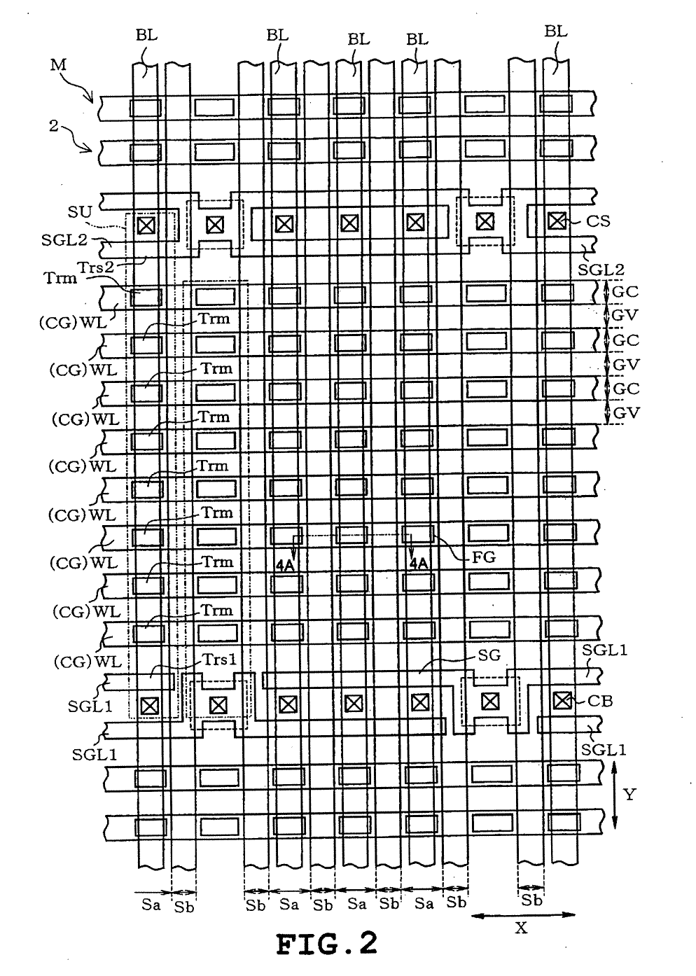

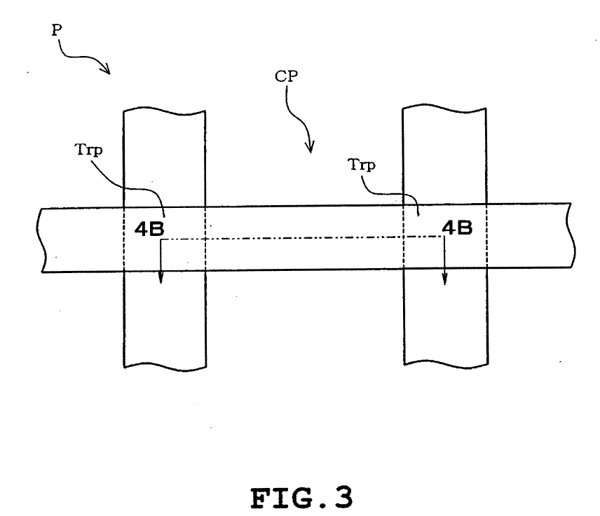

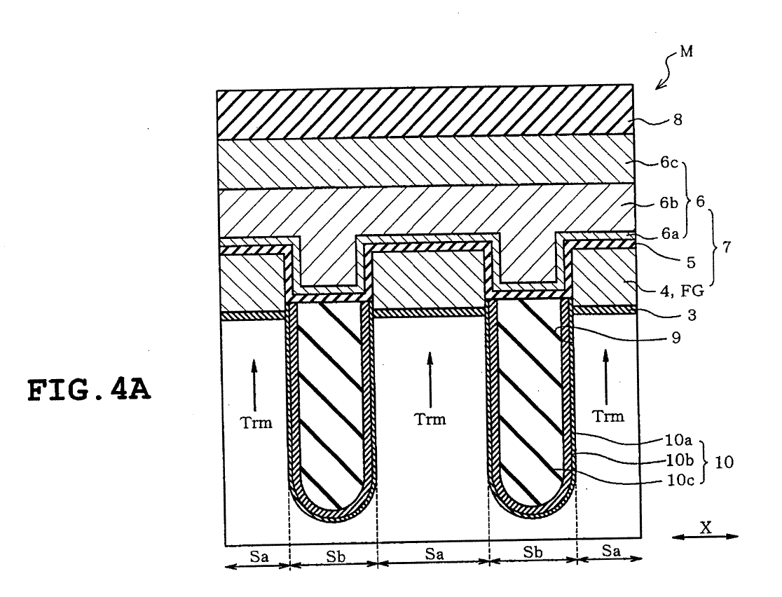

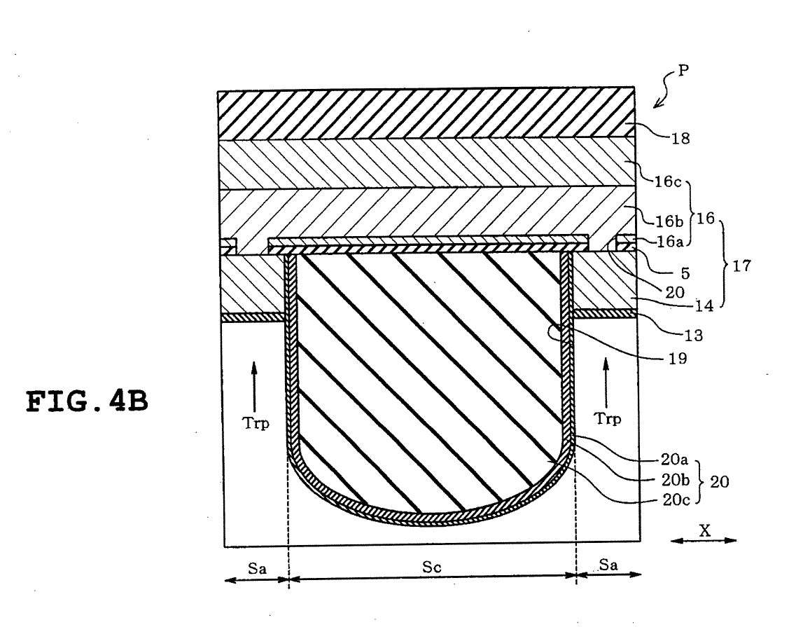

FIG. 1 is a circuit schematic equivalent to a part of memory cell array composed in a memory cell region of the NAND flash memory. FIG. 2 is a plan view showing the structure of a frame format of the memory cell region. FIG. 3 is a plan view showing the structure of a frame format of a peripheral circuit region. FIG. 4A is a longitudinally sectional view showing part of the memory cell region (sectional structure taken along line 4A-4A in FIG. 2). FIG. 4B is a sectional view showing a frame format of part of the peripheral circuit region (sectional structure taken along line 4B-4B in FIG. 3).

The NAND flash memory 1 serving as a semiconductor device is divided into a memory cell region M and a peripheral circuit region P. A memory cell array Ar is configured in the memory cell region M as shown in FIG. 1. A peripheral circuit Cp (for example, a peripheral transistor Trp) for driving the memory cell array Ar is configured in the peripheral circuit region P as shown in FIG. 3.

The memory cell array Ar configured in the memory cell region M comprises NAND cell units SU formed in a matrix. Each unit SU includes two selective gate transistors Trs1 and Trs2 and a plurality of memory cell transistors (for example, 8 or 2ⁿ where n is a positive integer) series connected between the selective gate transistors. In each NAND cell unit SU, the memory cell transistors Trm are formed by using a source/drain region (not shown) in common between the adjacent memory cell transistors Trm.

The memory cell transistors Trm arranged in the X direction (in the direction of a word line) in FIG. 1 are commonly connected by a word line (control gate line) WL. The selective gate transistors Trs1 arranged in the X direction in FIG. 1 are commonly connected by the selective gate lines SGL1. In the same way, the selective gate transistors Trs2 arranged in the X direction in FIG. 1 are commonly connected by the selective gate lines SGL2.

A bit line contact CB is connected to the drain region of the selective gate transistor Trs1. The bit line contact CB is connected to a bit line BL extending in the Y direction (serving as a bit line direction) perpendicular to the X direction in FIG. 1. Furthermore, each selective gate transistor Trs2 is connected via a source region to a source line SL extending in the X direction in FIG. 1.

FIG. 2 is a plan view showing a layout pattern of part of the memory cell region. A plurality of element isolation regions Sb each of which has a shallow trench isolation (STI) structure are formed in a p-type silicon substrate 2 so as to extend in the Y direction in FIG. 2. The element isolation regions Sb are formed in the X direction at predetermined intervals. As a result, a plurality of element regions (active regions) Sa are formed so as to be separated from each other in the X direction in FIG. 2.

Word lines WL of the memory cell transistors Trm are formed in the X direction perpendicular to the element regions Sa in FIG. 2. The word lines WL are constituted by connecting control gate electrodes CG of the memory cell transistors Trm and configured in gate electrode forming regions GC in FIG. 2. The word lines WL are formed so as to be spaced away from one another in the Y direction in FIG. 2. More specifically, the word lines WL are electrically separated from one another in the Y direction by interlayer insulating films buried in gate electrode separation regions GV.

Furthermore, the selective gate transistor Trs1 at the bit line contact CB side includes a pair of selective gate lines SGL1 formed in the X direction in FIG. 2 with a bit line contact CB being interposed therebetween. Bit line contacts CB are formed on the element region (active region) between the paired selective gate lines SGL1. Furthermore, the selective gate transistor Trs2 at the source line contact CS side includes a selective gate line SGL2 formed in the X direction in FIG. 2.

Floating gate electrodes FG of the memory cell transistors Trm are formed in regions where the word lines WL and the element regions Sa intersect with each other. The floating gate electrodes FG are aligned both in the X and Y directions. The word lines WL are formed over the plural element regions Sa and element isolation regions Sb so as to extend in the X direction in FIG. 2. The word lines WL are further formed over the floating gate electrodes FG aligned in the X direction. Furthermore, Selective gate electrodes SG of the selective gate transistors Trs1 are formed in regions where the selective gate lines SG and the element regions Sa intersect with each other. The selective gate electrodes SG are connected to the selective gate lines SGL1 in the X direction.

FIG. 4A is a sectional view taken along line 4A-4A in FIG. 2. As shown, each memory cell transistor Trm includes the floating gate electrode FG (polycrystalline silicon layer 4) formed on the gate insulating film 3 further formed on the p-type silicon substrate 2 serving as the semiconductor substrate, a stacked gate electrode 7 formed by stacking an intergate insulating film 5 and a control gate electrode 6, and source/drain regions (not shown) formed in a surface layer of the silicon substrate 2 so as to be located at both sides of the electrode 7 in the Y direction. The gate insulating film 3 is made from, for example, a silicon oxide film so as to serve as a tunnel insulating film. The floating gate electrode FG is formed in a polycrystalline silicon layer 4 doped with impurities such as phosphorus. As shown in FIG. 2, an intergate insulating film 5 is comprised of an oxide (silicon oxide film)-nitride (silicon nitride film)-oxide (silicon oxide film) (ONO) film, for example. The intergate insulating film 5 is formed so as to cover an upper surface and an upper side surface of the polycrystalline silicon layer 4 and further so as to serve as an interlayer insulating film and an interpoly insulating film.

A control gate electrode 6 is composed of two polycrystalline silicon layers 6a and 6b doped with impurities such as phosphorus and a low resistivity metal silicide layer 6c formed on the polycrystalline silicon layers. The low resistivity metal silicide layer 6c is comprised of, for example, tungsten silicide. A silicon nitride film 8 is formed on the low resistivity metal silicide layer 6c.

The selective gate transistors Trs1 and Trs2 have substantially the same structure as the memory cell transistors Trm although not shown. A hole (not shown) is formed through the intergate insulating film 5 and the polycrystalline silicon layer 6a so that the control gate electrode 6 of each memory cell transistor Trm and the polycrystalline silicon layer 4 are connected through the hole to each other structurally and electrically.

The gate insulating film 3 and the floating gate electrode FG both composing each memory cell transistor Trm are separated from each other in the X direction. Element isolation trenches 9 are formed between the polycrystalline silicon layers 4 of the memory cell transistors Trm adjacent to each other in the X direction and between the gate insulating films 3 in the upper part (surface layer) of the silicon substrate 2. An element isolation film 10 is formed in each element isolation trench 9, whereby each element isolation region Sb is formed.

Each element isolation region 9 has an upper end located higher than an upper surface of the gate insulating film 3 and lower than an upper surface of the floating gate electrode 4 so as to cover the underside of the polycrystalline silicon layer 4. Each element isolation film 10 is composed of a silicon oxide film 10a thinly formed along an inner surface (including an inner side wall surface) of each element isolation trench 9, a silicon oxide film 10b formed along an inner surface of the silicon oxide film 10a and a silicon oxide film 10c formed inside the silicon oxide film 10b. The silicon oxide film 10a is formed by a radical oxidation treatment, and the silicon oxide film 10b is a high temperature oxide (HTO) film formed by a low pressure chemical vapor deposition (LPCVD). The silicon oxide film 10c is a coating type silicon oxide film formed by thermal treatment of polysilazane coated by a coating process. The reason for a stacked structure of the element isolation film 10 is that an opening width of each element isolation trench 9 is reduced with recent miniaturization or refinement of elements and that the element isolation film 10 is desirably buried in the element isolation trench 9 with narrower opening width with the coating method.

Structure of Peripheral Circuit Region:

On the other hand, as shown in FIGS. 3 and 4B, peripheral circuits Cp are formed in the peripheral circuit region P. The peripheral circuits Cp include a plurality of n-channel MOS transistors Trp. A second element isolation region Sc is provided between these element regions (active areas) Sa thereby to isolate the element regions from each other. The transistors Trp of the peripheral circuit region P include the transistors of high breakdown voltage type and transistors of low breakdown voltage type. For example, the transistors Trp are configured so as to have a larger size than the memory cell transistors Trm. In the following description, elements of the peripheral circuit regions are labeled by reference numerals obtained by adding numeral 10 to the reference numerals of the elements in the memory cell region M. However, these elements of the peripheral circuit and memory cell regions P and M are made from the same material.

The transistors Trp of the peripheral circuit region P have a similar structure to the structure of the selective gate transistors Trs1 and Trs2. Each transistor Trp includes a gate electrode 17 formed on a gate insulating film 13 further formed on the silicon substrate 2 and a source/drain region (not shown) formed in the surface layer of the silicon substrate 2 so as to be located at both sides of the gate electrode 17 in the Y direction. The gate electrode 17 is formed by stacking polycrystalline silicon layers 14, 16a and 16b each doped with impurities such as phosphorus on the gate insulating film 13 sequentially and further by forming a low resistivity metal silicide layer 16c on the polycrystalline silicon layer 16b. A silicon nitride film 18 is formed on the low resistivity metal silicide layer 16c.

The polycrystalline silicon layers 16a and intergate insulating film 5 are formed between the polycrystalline silicon layers 14 and 16b composing the gate electrode 17. A through hole 20 is formed through the polycrystalline silicon layer 16a and the intergate insulating film 5 so that the polycrystalline silicon layers 14 and 16b are connected through the hole to each other structurally and electrically. The gate electrodes 17 of the transistors 17 adjacent to each other are connected by the polycrystalline silicon layers 16a and 16b and the low resistivity metal silicide layer 16c structurally and electrically in the embodiment. However, the structure of the gate electrode 17 maybe separated according to the configuration of the peripheral circuit Cp.

Element isolation trenches 19 are formed between the polycrystalline silicon layers 14 of the transistors Trp adjacent to each other in the X direction and between the gate insulating films 13 in the upper part (surface layer) of the silicon substrate 2. An element isolation film 20 is formed in each element isolation trench 19, whereby each element isolation region Sc is formed. The gate insulating films 13 and the polycrystalline silicon layers 14 of the transistors Trp adjacent to each other are isolated by the element isolation films 20 from each other in the X direction. The element isolation film 20 has an upper end which is located higher than an upper surface of the gate insulating film 13 and is substantially coplanar with an upper surface of the polycrystalline silicon layer 14.

The silicon oxide film 20a is formed by a radical oxidation treatment, and the silicon oxide film 20b is a high temperature oxide (HTO) film formed by a low pressure chemical vapor deposition (LPCVD) . The silicon oxide film 20c is a coating type silicon oxide film formed by thermal treatment of polysilazane coated by a coating process. More specifically, the element isolation region Sc has a structure similar to the structure of the element isolation region Sb between the memory cell transistors Trm, and the silicon oxide films 20a and 20b have the same film thicknesses as the silicon oxide films 10a and 10b respectively. The reason for employment of the similar structure is that the process is simplified by formation in the same steps.

The non-coating type silicon oxide film formed along the sidewall inner surfaces of the element isolation trenches 9 and 19 has a film thickness (total film thickness of the silicon oxide films 20a and 20b) equal to or larger than 23 nm. The reason for this is as follows. The coating type silicon oxide film 10c or 20c formed by the coating method has a larger film shrinkage factor than the silicon oxide film 10b or 20b formed by the LPCVD process. Accordingly, particularly as in the element isolation region Sc of the peripheral circuit region P, the silicon oxide film 20c peels or the silicon substrate 2 cracks in a region with a larger width than the element isolation region Sb of the memory cell region M (referred to as Si crack). In particular, the Si crack reaches the inside of the gate electrode 17 or silicon substrate 2. Accordingly, occurrence of crack needs to be prevented. As a matter of course, in the case where the silicon oxide film 10c or 20c peels, the peeling becomes a factor deteriorating the electrical characteristics when an electrically conductive film is formed on the silicon oxide film 10c or 20c. As a result, peeling should be suppressed as much as possible.

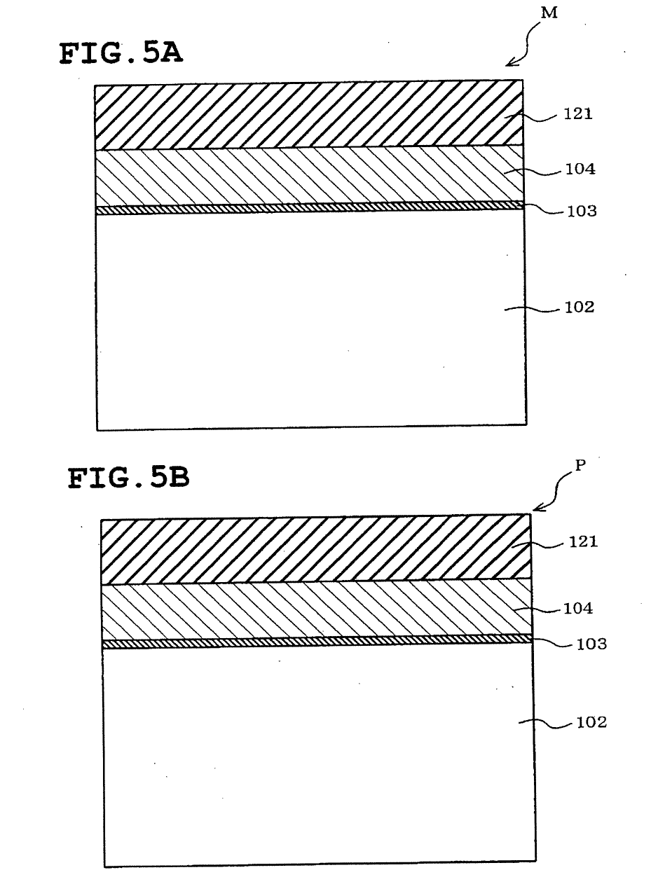

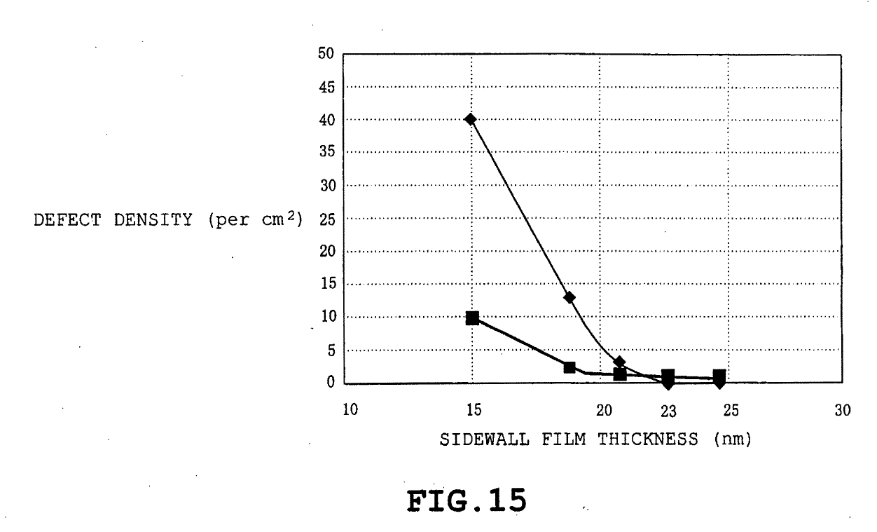

FIG. 15 shows a sidewall film thickness dependency of defect density in the peripheral circuit region. In the graph of FIG. 5, black squares denote a peeling characteristic of silicon, and black rhombuses denote the number of Si cracks occurred. As shown in FIG. 15, it can be confirmed that occurrence of Si crack and peeling can be suppressed as the total film thickness of silicon oxide films 20a and 20b is increased. In particular, occurrence of Si crack can be prevented when the total film thickness of the silicon oxide films 20a and 20b is equal to or larger than 23 nm. As obvious from the characteristic shown by the rhombuses, the number of cracks becomes zero when the total film thickness is at 23 nm or above.

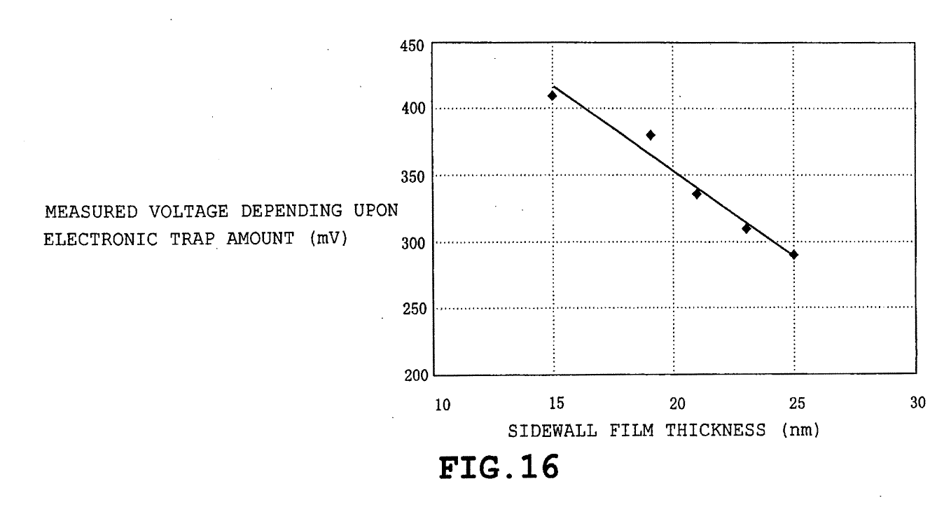

Furthermore, FIG. 16 shows a sidewall film thickness dependency of measured voltage depending upon an electronic trap amount. A threshold of a memory cell varies when write and erasure are repeated in the memory cell. However, the variations of the threshold can be suppressed when an electronic trap amount in the silicon oxide film 3 is reduced. FIG. 16 shows the voltage applied to the gate electrode when a predetermined constant current stress was applied to the silicon oxide film 3. It can be confirmed that the voltage is rendered lower and an electronic trap amount can be reduced as the total film thickness of the silicon oxide films 10a and 10b is increased. Accordingly, a better result can be achieved as the thicknesses of the films are increased. In further view of the defect density characteristic, a desirable result can be achieved when the total film thickness of the silicon oxide films 20a and 20b is equal to or larger than 23 nm.

An upper limit value of the total film thickness of the silicon oxide films 20a and 20b is determined to be in such a range that even when an upper part of the element isolation film 10 in the memory cell transistor forming region is closed by the silicon oxide film 10b having the same film thickness as the silicon oxide film 20b, polysilazane can be allowed to enter the void located below the silicon oxide film 10b. The upper limit value varies depending upon the width and depth of each element isolation trench 9.

A method of fabricating the NAND flash memory will now be described with reference to FIGS. 5 to 14B. One or more steps which will be described later may be eliminated. The films may be made from other materials than those described herein. Furthermore, the film thickness of each film may be changed. Additionally, for the sake of convenience in the description, the constituent elements in the fabrication (fabrication elements) corresponding to the elements of the films, layers and the like (structural elements) are labeled by reference numerals obtained by adding numeral 100 to the reference numerals affixed to the structural elements of the memory cell region M.

FIGS. 5A, 6A, 7, 8A, 9A, 10A, 11A, 12A, 13A and 14A are sectional views showing a frame format of the memory cell region during fabrication. FIGS. 5B, 6B, 7B, 8B, 9B, 10B, 11B, 12B, 13B and 14B are sectional views showing a frame format of the peripheral circuit region during fabrication. In the following description, when a figure number labeled with suffix “A” and a figure number labeled with suffix “B” correspond to each other, the steps of fabrication of the memory cell region N and the peripheral circuit region P are the same.

As shown in FIGS. 5A and 5B, a thermal oxidation treatment is applied to the surface of the silicon substrate 10 such that the silicon oxide film 103 with a thickness of 10 nm is formed. Subsequently, an amorphous silicon layer 104 doped with impurities such as phosphorus is deposited by 80 nm by the LPCVD process. The amorphous silicon layer 104 is polycrystallized by a subsequent thermal treatment. A silicon nitride film 121 with a film thickness of 100 nm is then deposited by the LPCVD process.

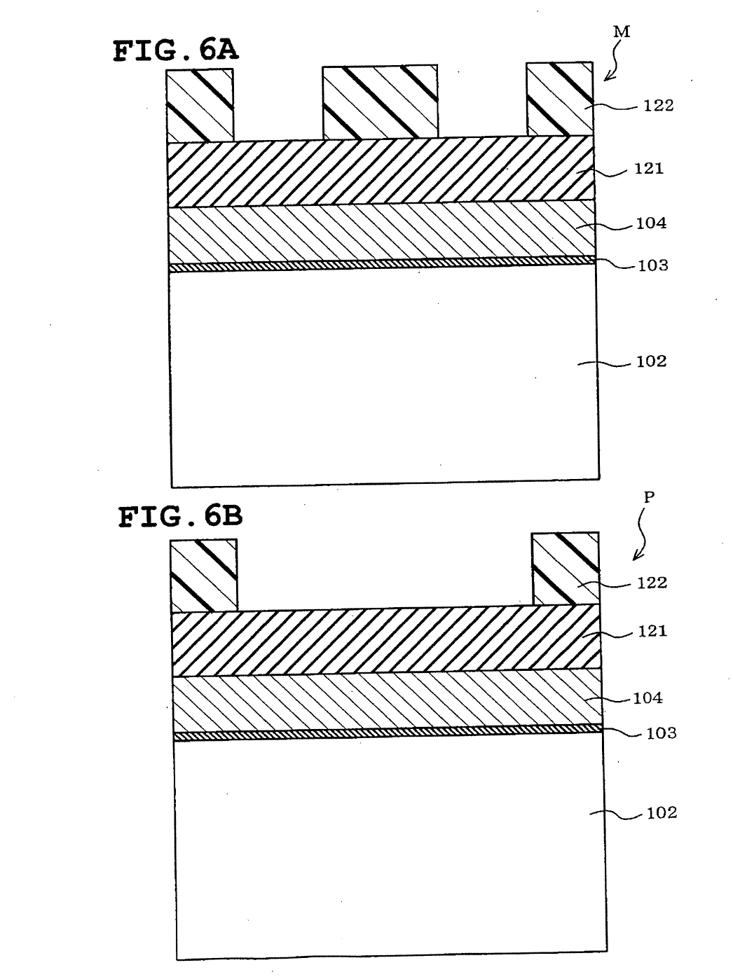

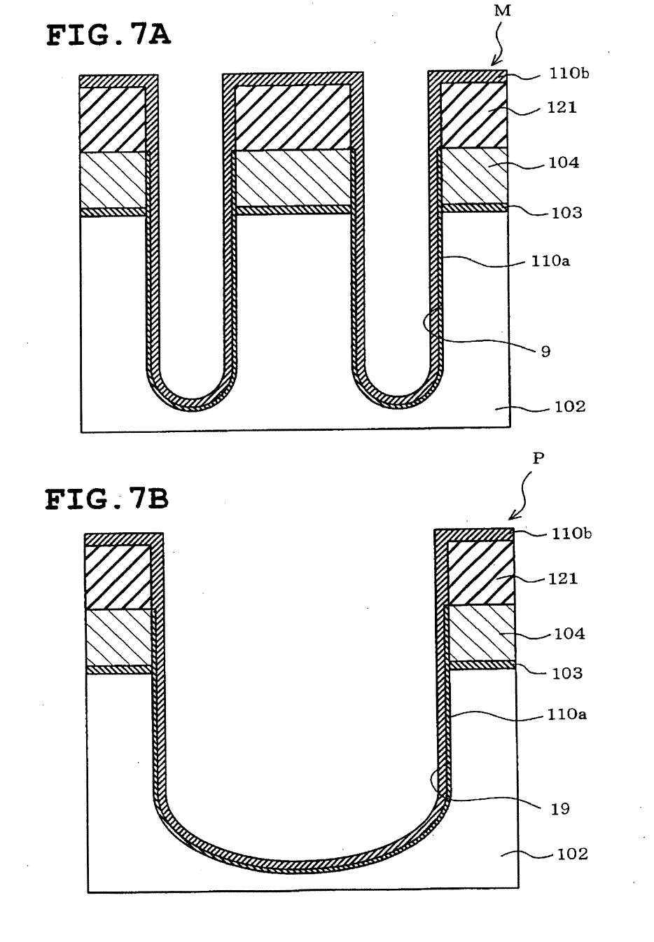

Next, as shown in FIGS. 6A and 6B, a resist 122 is applied onto the silicon nitride films 121 of both memory cell and peripheral circuit regions M and P thereby to be patterned into a desired shape. In this case, the opening pattern of the resist 122 is provided for formation of the aforesaid element isolation trenches 9 and 19. Subsequently, as shown in FIGS. 7A and 7B, the element isolation trenches 9 in the memory cell region M and the element isolation trenches 19 in the peripheral circuit region P are simultaneously formed in the silicon nitride film 121, amorphous silicon layer 104, silicon oxide film 103 and the upper surface of the silicon substrate 102 (surface layer) by a reactive ion etching (PIE) process with the resist 122 serving as a mask.

Subsequently, a radical oxidation treatment is carried out so that the silicon oxide films 110a with the same film thickness of 4 nm are formed along the inner surfaces of the element isolation trenches 9 and 19. In this case, the silicon oxide film 110a is formed mainly along the sidewall surface of the amorphous silicon layer 104, sidewall surface of the silicon oxide film 103, and sidewall surfaces and lower inner surfaces of the element isolation trenches 9 and 19 in the upper surface (surface layer) of the silicon substrate 102.

Subsequently, the silicon oxide films 110b are is formed along the inner surfaces of the silicon oxide films 110a in the element isolation trenches 9 and 19 in the memory cell and peripheral circuit regions M and P, so as to have the thicknesses of 19 nm or above, respectively. In this case, a higher coverage can be achieved when a HTO film is formed as the silicon oxide film 10b by the LPCVD process than when the silicon oxide film 110b is formed by the HDPCVD process. Furthermore, there is concern that bird beak would occur in the silicon oxide films 103 (corresponding to the gate insulating films 3 and 13) when the silicon oxide films 110a are formed along the inner surfaces of the element isolation trenches 9 and 19 by a thermal oxidation treatment. Accordingly, each silicon oxide film 110a are formed thinly by a radical oxidation treatment, and the silicon oxide film 110b is formed by the LPCVD process so as to cover the inner surface of the silicon oxide film 110a and so as to become thicker than the silicon oxide film 110a, so that the total film thickness is caused to become 23 nm or above.

Furthermore, when X1 designates a first opening width of each element isolation trench 9 of the memory cell region M and X2 designates a second opening width of each element isolation trench 19 of the peripheral circuit region P, the relationship between X1 and X2 is shown as X1<<X2 since the memory cell region M requires a high degree of integration. It has been confirmed that polysilazane 110c is allowed to be buried in a trench by coating when the opening width of the trench is not less than 5 nm. Accordingly, when the total film thickness of the silicon oxide films 110a and 110b is set so as to be less than a value obtained by (the first opening width X1)÷2−5, polysilazane 110c can desirably be buried in each trench. For example, when the first opening width X1 is set at 60 nm, the upper limit of film thickness can be obtained from (60÷2−5 nm).

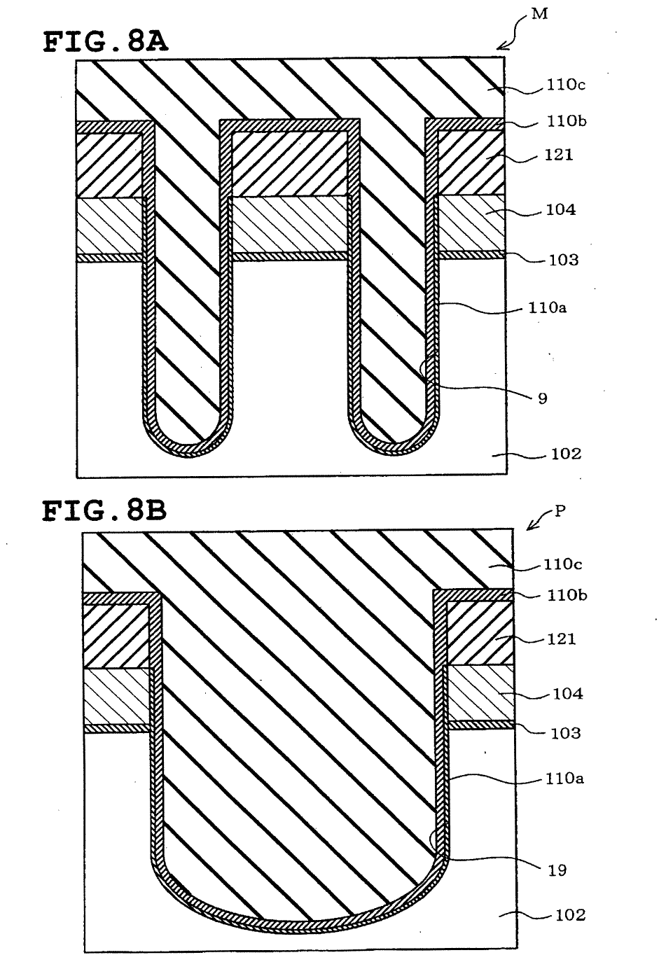

Subsequently, as shown in FIGS. 8A and 8B, polysilazane 110c is coated on the inside of the silicon oxide film 110b of each of the element isolation trenches 9 and 19 by the coating method. Next, thermal treatment is carried out in an oxidizing atmosphere from 400 to 500° C. so that polysilazane 11Oc is converted to a coated silicon oxidation film. In this case, there is a possibility that thermal shrinkage of polysilazane 110c may result in crack in the order of several μ or peeling of the polysilazane. However, as described above, since the silicon oxide films 110a and 110b are formed so that the total film thickness becomes 23 nm or above, occurrence of crack can be prevented and peeling of polysilazane 110c can be suppressed.

Moreover, the oxidation treatment is accelerated at an end of the silicon oxide film 103 by the influence of moisture content contained in polysilazane 110c as the result of thermal treatment, Consequently, there is concern that the film thickness would be increased and the performances of the gate insulating films 3 and 13 would be degraded. However, the aforesaid influence can be suppressed as much as possible since the total film thickness of the silicon oxide films 110a and 110b is set so as to be at 23 nm or above.

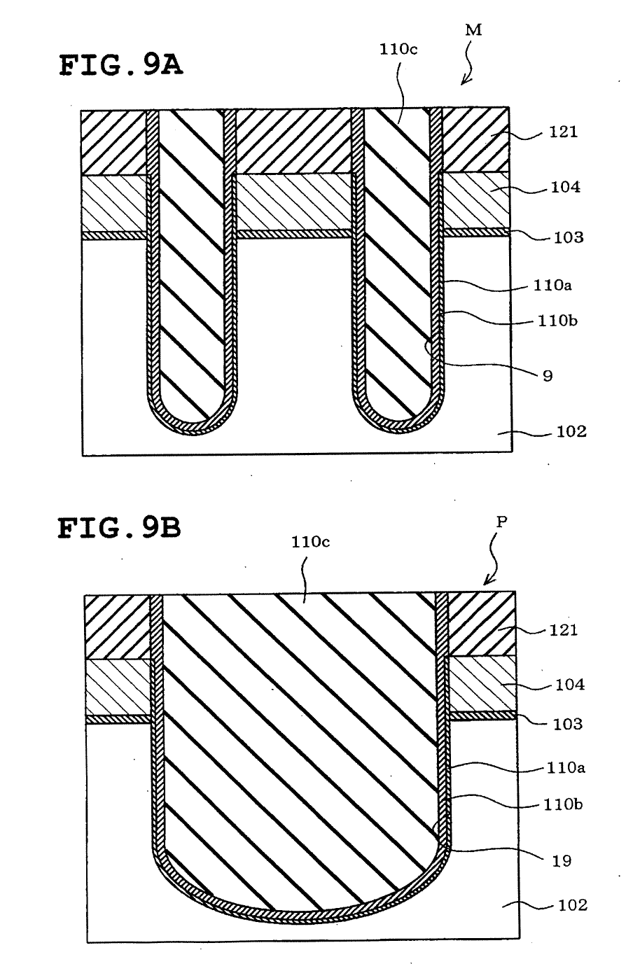

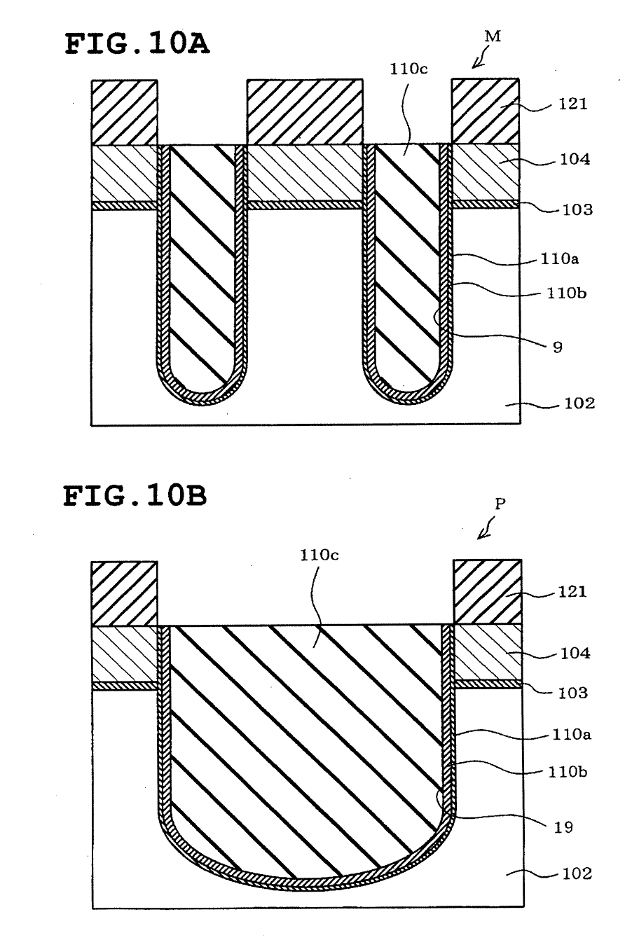

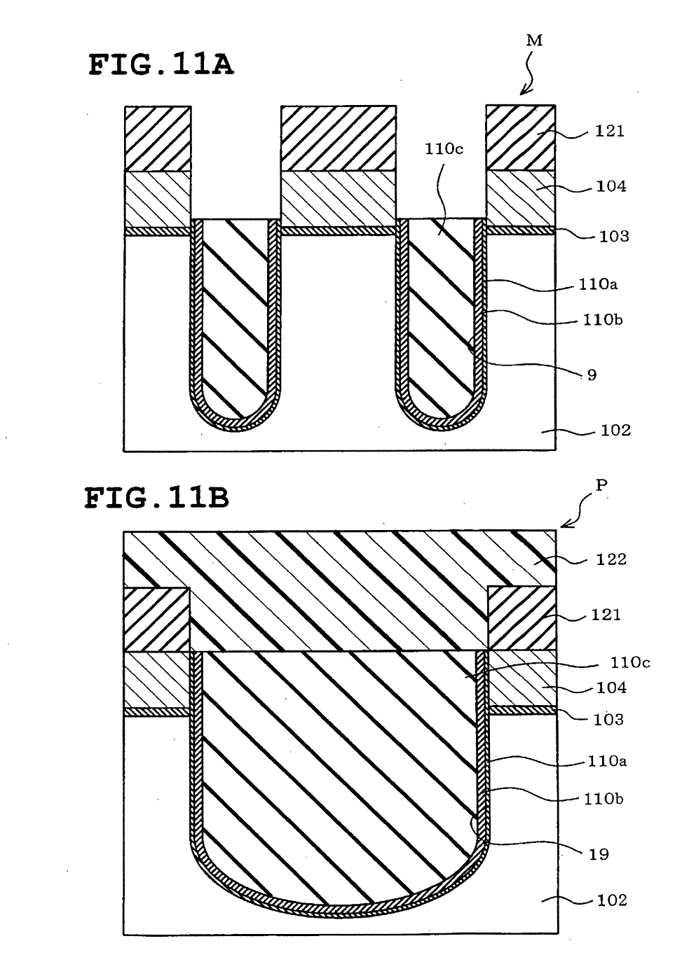

Subsequently, as shown in FIGS. 9A and 9B, upper portions of the silicon oxide film 110b and polysilazane 110c are planarized by a chemical mechanical polishing (CMP) process with the silicon nitride film 121 serving as a stopper. Subsequently, as shown in FIGS. 10A and 10B, the silicon oxide films 110a and 110b and polysilazane 110c are etched by the RIE process under the condition that higher selectivity is given to the silicon nitride film 121. Subsequently, as shown in FIGS. 11A and 11B, only the peripheral circuit region P is covered by the resist 122 so that the silicon oxide films 110a and 110b and polysilazane 110c of the memory cell region M are further etched.

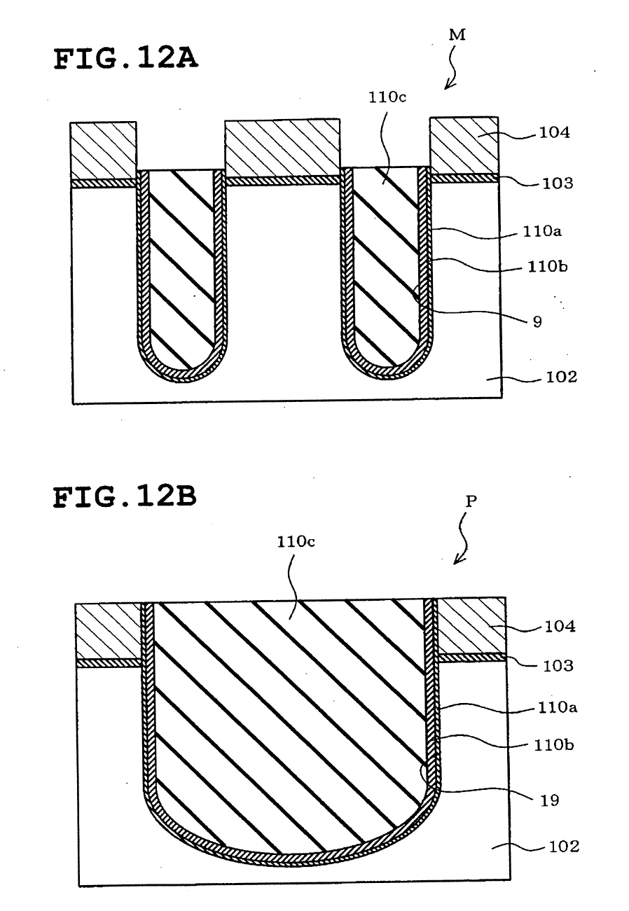

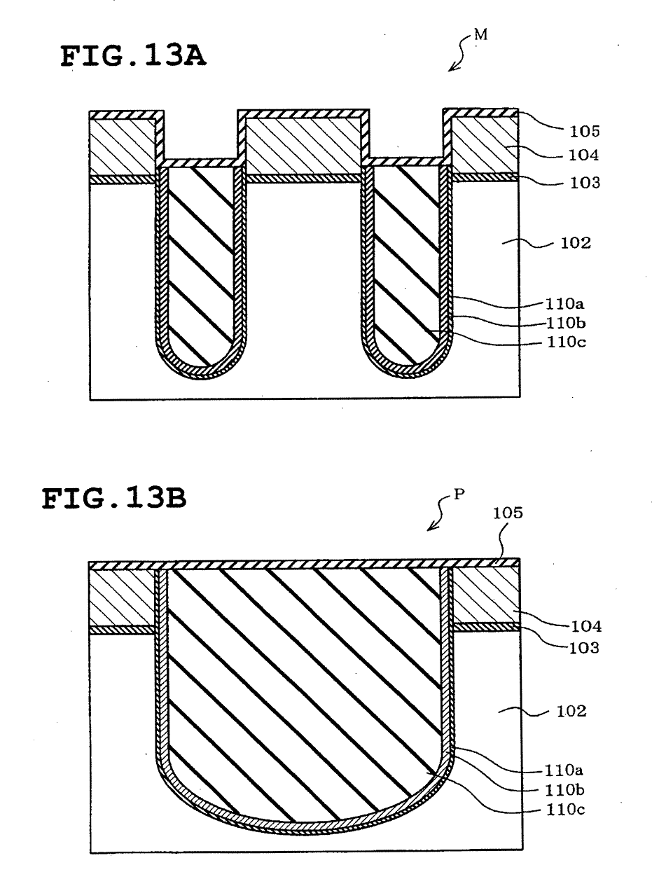

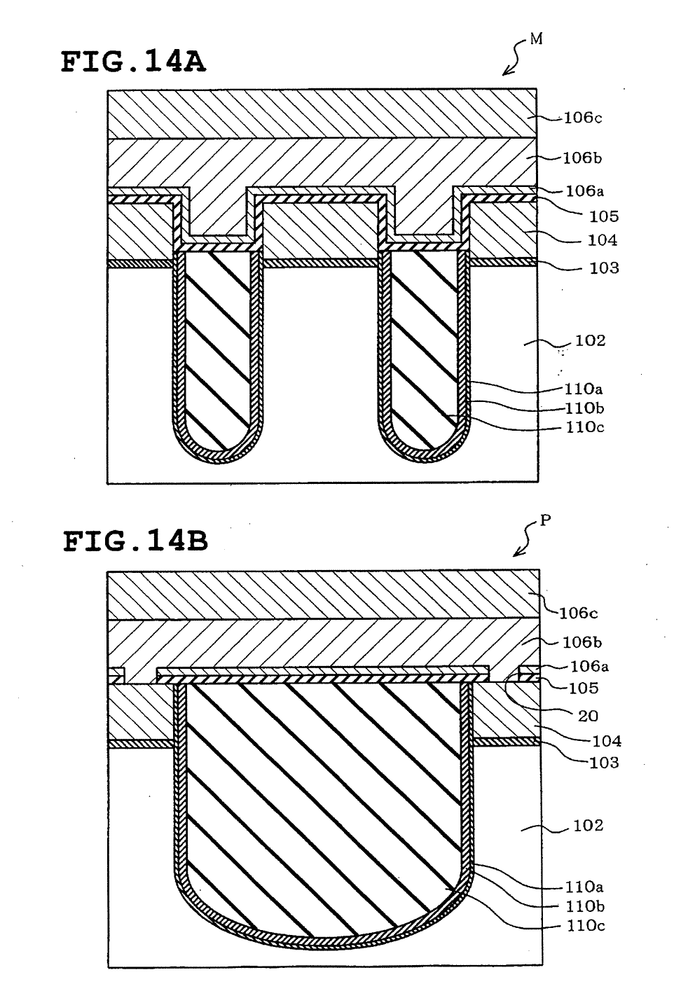

Subsequently, as shown in FIGS. 12A and 12B, the resist 122 is removed by an ashing treatment. Next, the silicon nitride film 121 is removed by a hot phosphate treatment. Subsequently, as shown in FIGS. 13A and 13B, ONO films 105 each with a film thickness of about 15 nm are formed in the memory cell and peripheral circuit regions M and P by LPCVD process respectively. Each ONO film 105 has a stacked structure of a silicon oxide film, silicon nitride film and silicon oxide film. Subsequently, as shown in FIGS. 14A and 14B, amorphous silicon films 106a each doped with impurities such as phosphorus are formed on the ONO films 105 of the memory cell and peripheral circuit regions M and P respectively. A through hole 20 is formed through the amorphous silicon film 106a and ONO film 105 of the peripheral circuit region P, and thereafter, amorphous silicon films 106b are deposited in each of the memory cell and peripheral circuit regions M and P. The amorphous silicon film 104 of the peripheral circuit region P is connected through the hole 20 to the amorphous silicon film 106b. Next, tungsten silicide 106c is formed on the upper surface of the amorphous silicon film 106b. The amorphous silicon films 106a and 106b are polycrystallized by a subsequent thermal treatment. Subsequently, fabrication of the NAND flash memory device 1 is completed after execution of wiring and other steps although the description of these steps will be eliminated.

As obvious from the foregoing, the silicon oxide films 110a and 110b are formed along the inner surfaces of the element isolation trenches 9 and 19 of the memory cell and peripheral circuit regions 9 and 19 so as to have the total film thickness of 23 nm. Even when polysilazane 110a, 110b is subsequently coated and thermally treated, occurrence of crack can be prevented and the peeling of polysilazane can be suppressed.

The invention should not be limited by the foregoing embodiment. The embodiment may be modified or expanded as follows. Although the stacked structure employed in the embodiment includes the radical oxidated silicon oxide film 10a and the silicon oxide film 10b formed by LPCVD process, a single layer of silicon oxide film 10b formed by the LPCVD process may be employed.

Although the stacked structure employed in the embodiment includes the silicon oxide film 20a formed by the radical oxidation treatment and the silicon oxide film 20b formed by LPCVD process, a single layer of silicon oxide film 20b formed by the LPCVD process may be employed.

The intergate insulating film 5 may comprise an insulating film layer with a stacked structure of oxidation film layers and nitride film layers such as NONON (silicon nitride film-silicon oxide film-silicon nitride film-silicon oxide film-silicon nitride film). Alternatively, the intergate insulating film 5 may comprise a film made from a high dielectric material.

Although the element isolation regions Sb and Sc are formed in the memory cell region M and the peripheral circuit region P in the foregoing embodiment, the invention may be applied to EEPROMs, EPROMs, NOR flash memories when the opening widths of the element isolation trenches 9 and 19 are large sufficient to allow the silicon oxide films 10a and 10b to be formed in the trenches through the openings. Furthermore, the invention may be applied to other non-volatile semiconductor storage devices, semiconductor storage devices or semiconductor devices.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate formed with at least two element isolation trenches having a first opening width and a second opening width larger than the first opening width, respectively;
a non-coating type silicon oxide film formed along an inner surface of each element isolation trench so as to have a film thickness equal to or larger than 23 nm; and
a coating type silicon oxide film formed inside the non-coating type silicon oxide film in each element isolation trench.

2. The semiconductor device according to claim 1, wherein the non-coating type silicon oxide film has a film thickness less than a value obtained from an expression of (the first opening width)÷2−5 (nm).

3. The semiconductor device according to claim 1, wherein the non-coating type silicon oxide film includes a first oxide film formed by a radical oxidation treatment and a second oxide film formed by a low pressure chemical vapor deposition (LPCVD) process.

4. The semiconductor device according to claim 2, wherein the non-coating type silicon oxide film includes a first oxide film formed by a radical oxidation treatment and a second oxide film formed by a low pressure chemical vapor deposition (LPCVD) process.

5. The semiconductor device according to claim 1, wherein the non-coating type silicon oxide film is formed into a single layer by a low pressure chemical vapor deposition (LPCVD) process.

6. The semiconductor device according to claim 2, wherein the non-coating type silicon oxide film is formed into a single layer by a low pressure chemical vapor deposition (LPCVD) process.

7. A semiconductor device comprising:
a semiconductor substrate including:
a memory cell region having a plurality of first element isolation trenches with first opening widths respectively and a plurality of memory cell elements formed on first active regions divided by the first element isolation trenches; and
a peripheral circuit region having a second element isolation trench with a second opening width larger than the first opening widths of the first element isolation trenches, and having peripheral circuit elements formed on second active regions divided by the second element isolation trenches;
a non-coating type silicon oxide film formed along an inner surface of each element isolation trench so as to have a film thickness equal to or larger than 23 nm; and
a coating type silicon oxide film formed inside the non-coating type silicon oxide film in each element isolation trench.

8. The semiconductor device according to claim 7, wherein the non-coating type silicon oxide film has a film thickness less than a value obtained from an expression of (the first opening width)÷2−5 (nm).

9. The semiconductor device according to claim 7, wherein the non-coating type silicon oxide film includes a first oxide film formed by a radical oxidation treatment and a second oxide film formed by a low pressure chemical vapor deposition (LPCVD) process.

10. The semiconductor device according to claim 8, wherein the non-coating type silicon oxide film includes a first oxide film formed by a radical oxidation treatment and a second oxide film formed by a low pressure chemical vapor deposition (LPCVD) process.

11. The semiconductor device according to claim 7, wherein the non-coating type silicon oxide film is formed into a single layer by a low pressure chemical vapor deposition (LPCVD) process.

12. The semiconductor device according to claim 8, wherein the non-coating type silicon oxide film is formed into a single layer by a low pressure chemical vapor deposition (LPCVD) process.

13. A method of fabricating a semiconductor device, comprising:
forming in a semiconductor substrate a plurality of element isolation trenches having different opening widths;
forming a non-coating type silicon oxide film along an inner surface of each element isolation trench so that the non-coating type silicon oxide film has a film thickness equal to or larger than 23 nm; and
forming a coating type silicon oxide film inside the non-coating type silicon oxide film formed in each element isolation trench.

14. The method according to claim 13, wherein in the step of forming the non-coating type silicon oxide film, a first oxide film formed by a radical oxidation treatment and a second oxide film formed by a low pressure chemical vapor deposition (LPCVD) process are stacked.

15. The method according to claim 13, wherein in the step of forming the non-coating type silicon oxide film, the non-coating type silicon oxide film is formed into a single layer by a low pressure chemical vapor deposition (LPCVD) process.
